(19) United States
(12) Patent Application Publication
(10) Pub. No.: US 2006/0022339 A1
(43) Pub. Date: Feb. 2, 2006

(54) Solder ball opening protrusion for semiconductor assembly

(75) Inventor: Akira Matsunami, Beppu-city (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/903,741

(22) Filed: Jul. 30, 2004

(51) Int. Cl. H01L 23/48

(52) U.S. Cl. 257/738

(57) ABSTRACT

A ball grid array (“BGA”) package substrate, comprising a metallic core, a layer of copper abutting at least a portion of said core, a layer of nickel abutting at least a portion of the layer of copper, a layer of gold abutting at least some of the layer of nickel, and a solder ball opening abutting at least some of the layer of gold, wherein the solder ball opening comprises a protrusion, said protrusion comprising an inner copper layer, an outer gold layer, and a nickel layer situated therebetween.

### BACKGROUND

A ball grid array (“BGA”) package is a type of chip package wherein solder balls are used to electrically connect the BGA package to a structure external to the package, such as a printed circuit board (“PCB”). These solder balls conduct electrical signals between a chip inside the package and the external structure. BGA packages are substantially useful for chips having a considerable number of connections (e.g., a microprocessor).

Solder balls are connected to a BGA package substrate at points called “solder ball openings” found on the BGA package substrate. FIG. 1a shows an exemplary BGA package substrate 100 comprising a metallic substrate core 10 (e.g., a silicon core, a sapphire core), a copper layer 20, a solder mask 30 and a solder ball opening 70 comprising a nickel layer 40, a gold layer 50, and a solder ball pad area 62. The BGA package substrate 100 also comprises a bond pad opening 72 comprising a nickel layer 42, a gold layer 52 and a bond pad area 60. The BGA package substrate 100 transfers electrical signals between a chip (not shown) mounted abutting the BGA package substrate 100 and one or more solder balls electrically connected to the BGA package substrate 100 (e.g., by way of a solder reflow process).

More specifically, the chip may be electrically connected to the BGA package substrate 100 at the bond pad area 60 using any suitable wirebond connection established by way of a solder reflow process. The gold layer 52 provides wetting for a soldering process wherein the wirebond is mated to the bond pad area 60. The nickel layer 42 serves as a barrier layer between the gold layer 52 and the copper layer 20. Electrical signals transferred from the chip to the bond pad area 60 are carried through the copper layer 20 toward the solder ball opening 70. The electrical signals then are transferred to a solder ball (not shown) soldered into the solder ball pad area 62. Similar to the gold layer 52, the gold layer 50 provides wetting for the solder ball and dissolves during the soldering process. The nickel layer 40 serves as a barrier layer between the gold layer 52 and the copper layer 20. FIG. 1b shows a detailed view of a portion of the BGA package substrate 100 comprising the solder ball opening 70. Once a solder ball 104 is electrically connected to the BGA package 100 at the solder ball opening 70, a solder joint 106 is formed, as shown in FIG. 1c.

Compared to a pin grid array (“PGA”) package that uses pins to form electrical connections between a chip inside the package and a structure external to the package, the BGA package substrate 100 has increased levels of electrical and thermal performance and occupies less space than the PGA package substrate. However, the BGA package substrate 100 does not have the flexibility of a PGA package substrate under conditions of extreme temperature and mechanical stress. For this reason, the solder joint 106 may crack or otherwise become damaged under such extreme conditions. As a result of the weakened solder joint 106, the solder ball 104 connected to the solder joint 106 may detach from the BGA package substrate 100, possibly rendering the BGA package substrate 100 (as well as the chip mounted abutting the BGA package substrate 100) useless.

### BRIEF SUMMARY

The problems noted above are solved in large part by a ball grid array package substrate comprising a protrusion in a solder ball opening. One exemplary embodiment may comprise a metallic core, a layer of copper abutting at least a portion of said core, a layer of nickel abutting at least a portion of the layer of copper, a layer of gold abutting at least some of the layer of nickel, and a solder ball opening abutting at least some of the layer of gold, wherein the solder ball opening comprises a protrusion, said protrusion comprising an inner copper layer, an outer gold layer, and a nickel layer situated therebetween.

### BRIEF DESCRIPTION OF THE DRAWINGS

For a detailed description of exemplary embodiments of the invention, reference will now be made to the accompanying drawings in which:

FIG. 1a shows an exemplary BGA package substrate;

FIG. 1b shows a portion of the BGA package substrate of FIG. 1a;

FIG. 1c shows a solder ball electrically connected to the portion of the substrate shown in FIG. 1b;

FIG. 2a shows a portion of the BGA package substrate having a solder ball opening protrusion, in accordance with a preferred embodiment of the invention;

FIGS. 2b and 2c show various protrusion shapes in accordance with embodiments of the invention;

FIG. 2d shows a solder ball electrically connected to the substrate portion of FIG. 2a, in accordance with a preferred embodiment of the invention;

FIG. 3 shows a detailed view of a portion of the BGA package substrate in accordance with a preferred embodiment of the invention;

FIG. 4a shows a flow diagram in accordance with embodiments of the invention; and

FIGS. 4b-1-4b-10 a process flow diagram in accordance with embodiments of the invention.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

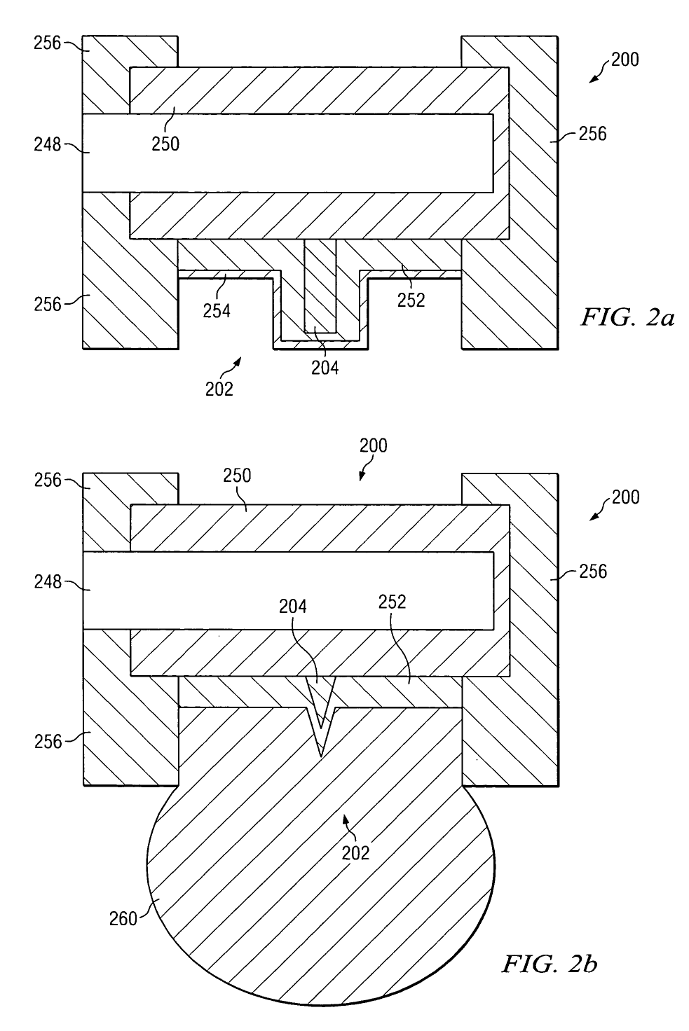

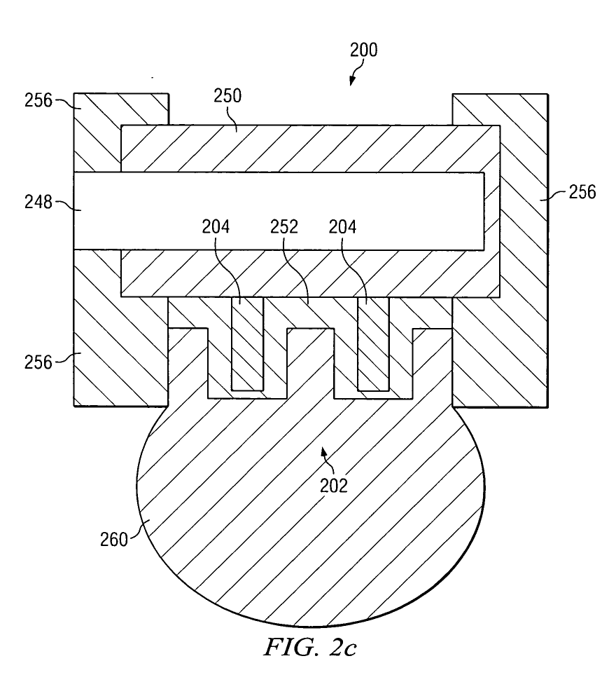

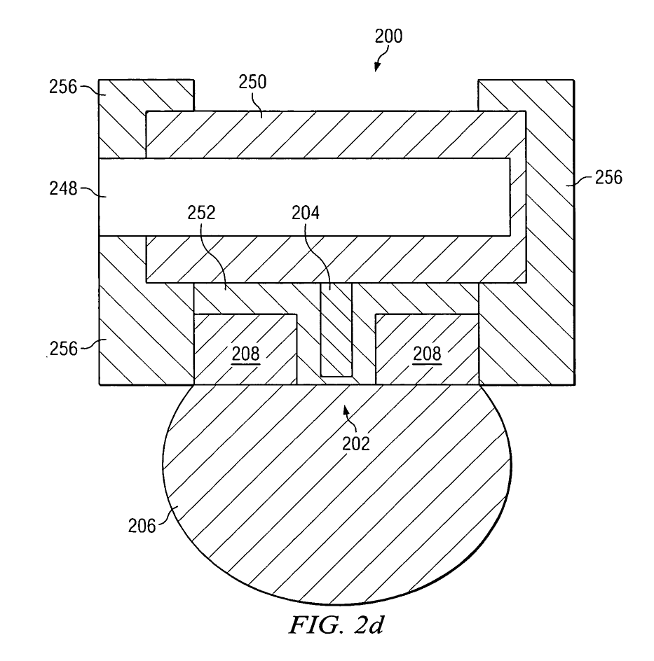

Presented herein is a design for a solder ball opening on a BGA package substrate that prevents the aforementioned problems of solder joint weakening and solder ball detachment. FIG. 2a shows a portion of an exemplary BGA package substrate 200 comprising a solder ball opening 202. In some embodiments, the BGA package substrate 200 may be a micro-BGA substrate or a nano-fine pitch BGA substrate. Similar to the BGA package substrate 100, the BGA package substrate 200 comprises a solder mask 256, a copper layer 250 surrounding a core 248, a nickel layer 252 adjacent the copper layer 250, a gold layer 254 adjacent the nickel layer 252. The solder ball opening 202 contains a protrusion 204 used to provide additional, mechanical support to a solder joint that may be formed during the coupling of a solder ball to the solder ball opening 202. The protrusion 204 is an extension of the copper layer 256 and comprises the nickel layer 252 and the gold layer 254 as shown. The protrusion 204 preferably is of a substantially cuboidal shape, although the scope of disclosure is not limited to any particular shape or size. For example, the shape of the protrusion 204 may be irregular, substantially spherical, or substantially conical as shown in FIG. 2b. The solder ball opening 202 may even contain multiple protrusions 204, as shown in FIG. 2c.

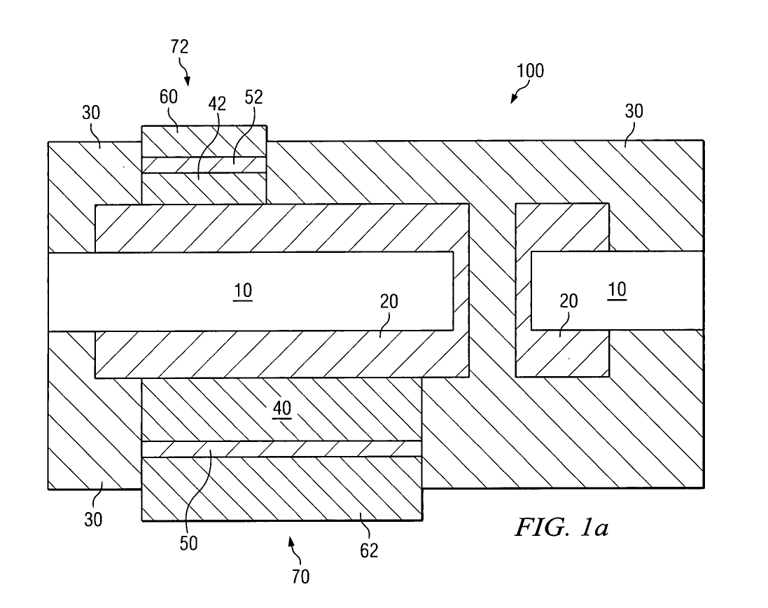

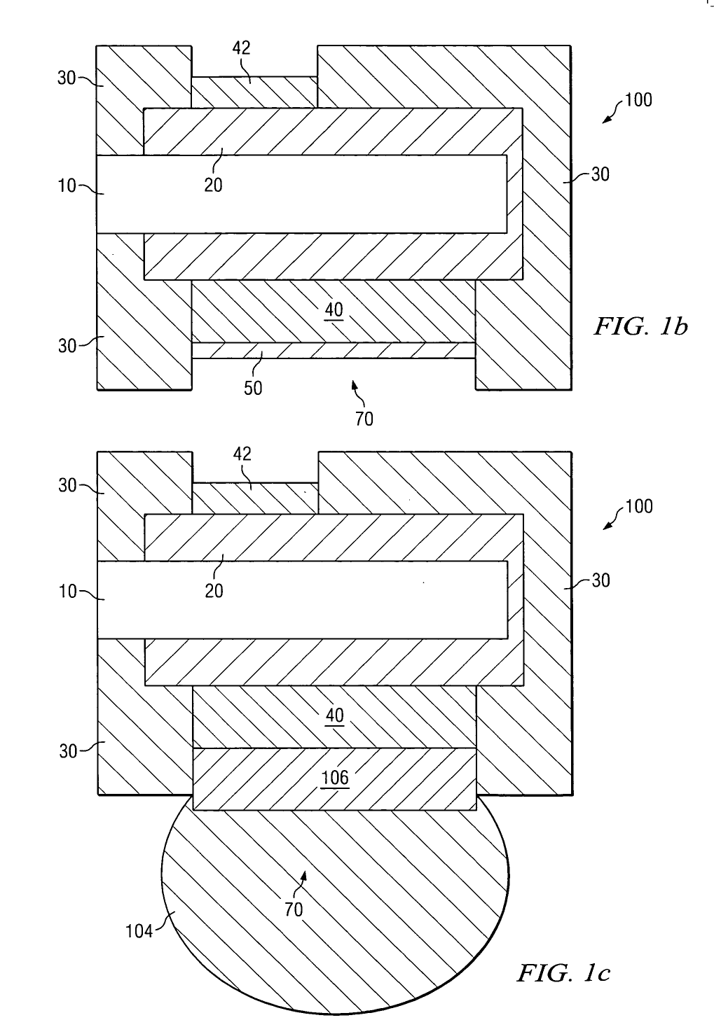

FIG. 2d shows the BGA package substrate 200 electrically connected to a solder ball 206 at the solder ball opening 202, thus forming a solder joint 208. Unlike the solder ball joint 106 of FIG. 1b, because of the protrusion 204, the solder ball joint 208 is able to withstand extreme temperatures and mechanical stress. As such, the solder joint 208 is less likely to crack, thereby keeping the solder ball 206 intact and electrically connected to the BGA package substrate 200.

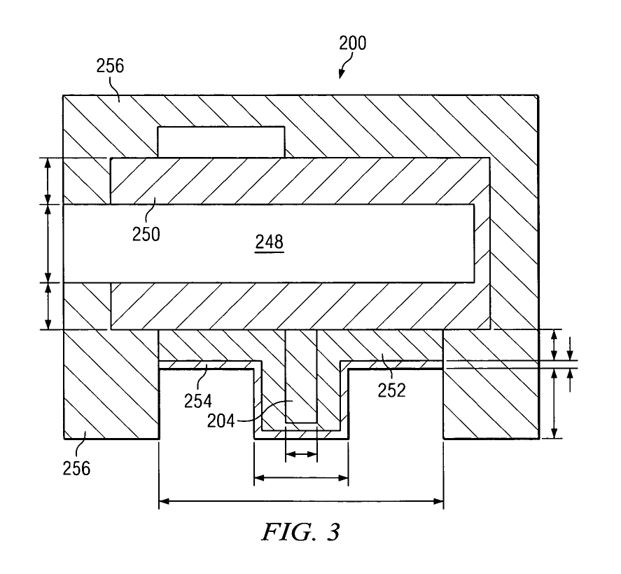

FIG. 3 shows a detailed view of the portion of the BGA package substrate 200 shown in FIGS. 2a and 2d. As indicated by the corresponding arrows on the figure, the width of the copper layer 250 on each side of the core 248 preferably is approximately between 15 and 20 micrometers, the width of the nickel layer 252 between the copper layer 250 and the gold layer 254 preferably is approximately between 1 and 2 micrometers, the width of the gold layer 254 preferably is approximately between 0.1 and 0.3 micrometers, the length of the solder ball opening 202 preferably is approximately between 250 and 280 micrometers, and the width of the solder ball opening 202 preferably is approximately between 45 and 50 micrometers. The copper layer 250 of the protrusion 204 preferably is approximately between 30 and 35 micrometers in width and the entire protrusion 204 preferably is approximately between 35 and 40 micrometers in width. The scope of disclosure is not limited to these preferred metal layer parameters.

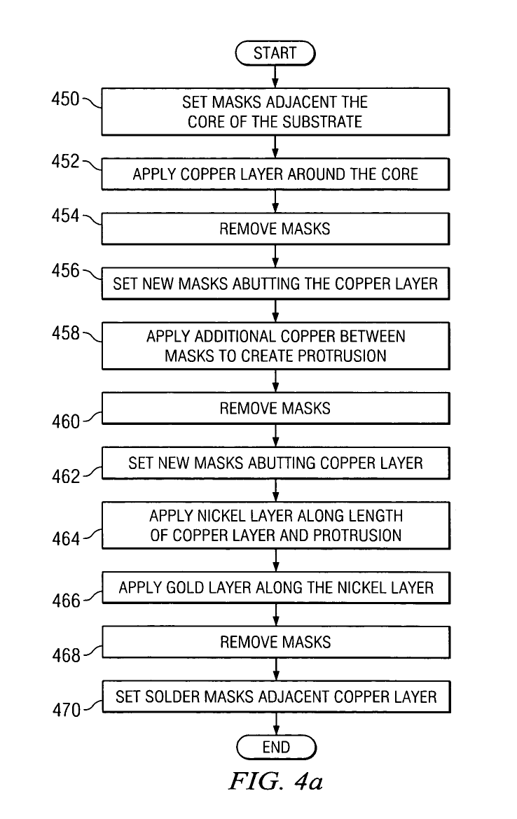

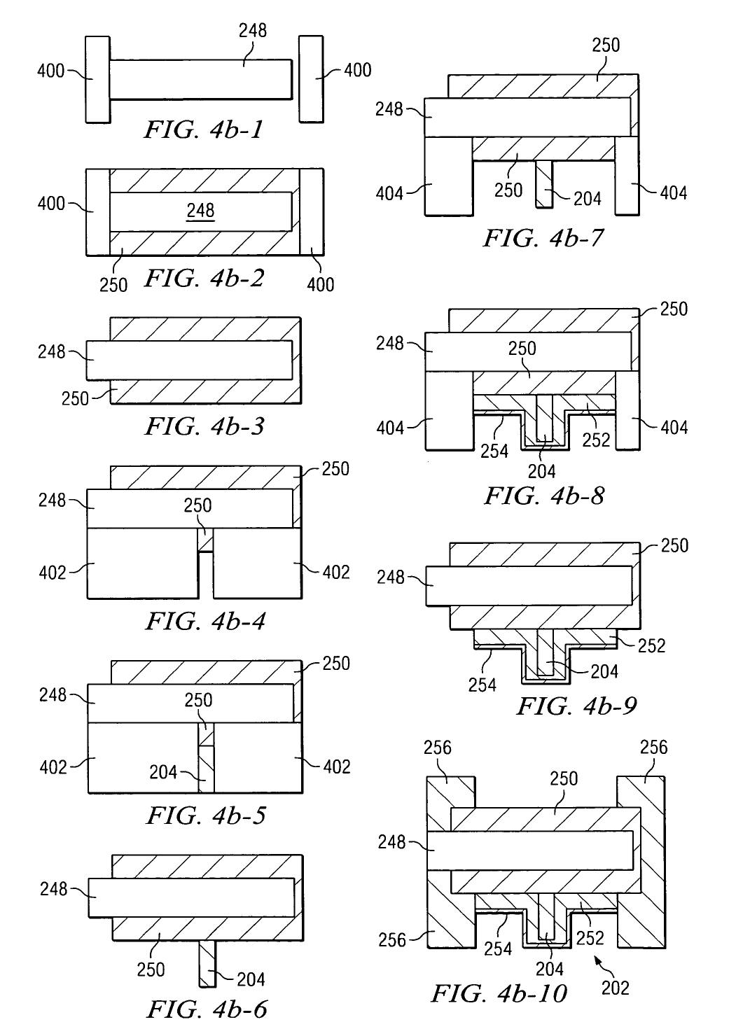

FIGS. 4a and 4b show a process that may be used to implement the BGA package substrate 200 of FIG. 3. More specifically, FIG. 4a shows a flow diagram of the process and FIGS. 4b-1-4b-10 show an assembly flow diagram of the process. The process may begin by setting masks 400 adjacent the core 248, as shown (block 450 and FIG. 4b-1). The process is continued by applying the copper layer 250 around the core 248 (block 452 and FIG. 4b-2) and then removing the masks 400 (block 454 and FIG. 4b-3). The process is continued further by setting masks 402 abutting the copper layer 250 (block 456 and FIG. 4b-4), applying additional copper between the masks 402 to create the protrusion 204 (block 458 and FIG. 4b-5), and removing the masks 402 (block 460 and FIG. 4b-6). The process continues by setting masks 404 abutting the copper layer 250 (block 462 and FIG. 4b-7), applying the nickel layer 252 (block 464 and FIG. 4b-8) and the gold layer 254 (block 466 and 4b-8) between the masks 404 and adjacent the copper layer 250 and the protrusion 204, and removing the masks 404, as shown (block 468 and FIG. 4b-9). Finally, the solder masks 256 are set adjacent the copper layer 250 (block 470 and FIG. 4b-10) in preparation for a solder reflow process wherein the solder ball 206 of FIG. 2d is electrically connected to the solder ball opening 202.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A ball grid array (“BGA”) package substrate, comprising:
a metallic core;
a layer of copper abutting at least a portion of said core;
a layer of nickel abutting at least a portion of the layer of copper;
a layer of gold abutting at least some of the layer of nickel; and
a solder ball opening abutting at least some of the layer of gold;
wherein the solder ball opening comprises a protrusion, said protrusion comprising an inner copper layer, an outer gold layer, and a nickel layer situated therebetween.

2. The substrate of claim 1, wherein the layer of copper is approximately between 15 and 20 micrometers in width.

3. The substrate of claim 1, wherein the layer of nickel is approximately between 1 and 2 micrometers in width.

4. The substrate of claim 1, wherein the layer of gold is approximately between 0.1 and 0.3 micrometers in width.

5. The substrate of claim 1, wherein the inner copper layer is approximately between 30 and 35 micrometers in width.

6. The substrate of claim 1, wherein the protrusion is approximately between 35 and 40 micrometers in width.

7. The substrate of claim 1, wherein the solder ball opening is approximately between 250 and 280 micrometers in length.

8. The substrate of claim 1, wherein the core is approximately 100 micrometers in width.

9. The substrate of claim 1, wherein the protrusion is substantially cuboidal in shape.

10. The substrate of claim 1, wherein the protrusion is irregular in shape.

11. The substrate of claim 1, wherein the protrusion is conical in shape.

12. The substrate of claim 1, wherein the substrate is a micro-BGA substrate.

13. The substrate of claim 1, wherein the substrate is a nano-fine pitch BGA.

14. The substrate of claim 1, further comprising another protrusion that extends through the solder ball opening, wherein the protrusions are substantially parallel to each other.

15. The substrate of claim 1, wherein the solder ball opening is approximately between 45 and 50 micrometers in width.

16. The substrate of claim 1, wherein the protrusion extends approximately between 45 and 50 micrometers through the solder ball opening.

17. A method, comprising:
applying a copper layer abutting at least a portion of a BGA package substrate core;
applying additional copper to create a protrusion that extends into a solder ball opening;
applying a nickel layer abutting at least some of the copper layer and the protrusion; and
applying a gold layer abutting at least a portion of the nickel layer.

18. The method of claim 17, wherein the steps of applying a copper layer, applying additional copper, applying a nickel layer, and applying a gold layer comprise using masks.

19. The method of claim 17, wherein applying a copper layer abutting at least a portion of a BGA package substrate core comprises applying a copper layer abutting at least a portion of a substrate core selected from a group consisting of a micro-BGA package substrate core and a nano-fine pitch BGA package substrate core.

20. The method of claim 17, wherein applying additional copper to create a protrusion comprises applying additional copper to create a protrusion having a shape selected from a group consisting of an irregular shape, a spherical shape, a cuboidal shape and a conical shape.

21. The method of claim 17, further comprising applying additional copper to create a second protrusion that extends into the solder ball opening, said second protrusion substantially parallel to the protrusion.

22. The method of claim 17, wherein applying additional copper to create a protrusion comprises applying additional copper to create a protrusion that is approximately between 30 and 35 micrometers in width.
